(19) United States
(12) Patent Application Publication
(10) Pub. No.: US 2017/0110362 A1
(43) Pub. Date: Apr. 20, 2017

(54) SOI STRUCTURE AND FABRICATION METHOD

(71) Applicant: ZING SEMICONDUCTOR CORPORATION, Shanghai (CN)

(72) Inventors: DEYUAN XIAO, Shanghai (CN); RICHARD R. CHANG, Shanghai (CN)

(21) Appl. No.: 15/166,015

(22) Filed: May 26, 2016

(30) Foreign Application Priority Data
Oct. 20, 2015 (CN) 201510683914.7

(51) Int. Cl. H01L 21/762; H01L 29/06; H01L 29/32; H01L 21/30

(52) U.S. Cl. CPC H01L 21/76254; H01L 21/3003; H01L 29/0649; H01L 29/32

(57) ABSTRACT

Present embodiments provide for A SOI substrate and fabricating method thereof are provided. The fabricating method of SOI substrate comprises: providing a first substrate, wherein a first dielectric layer is formed on the first substrate; implanting deuterium ions into the first substrate, wherein a deuterium-impurity layer is formed in the first substrate at predetermined depth; providing a second substrate, wherein a second dielectric layer is formed on the second substrate and bounded with the first dielectric layer; performing an annealing process, wherein microbubbles are formed in the deuterium-impurity layer; and cutting the first substrate from the deuterium-impurity layer to obtain the SOI substrate.

### INCORPORATION BY REFERENCE

This application claims priority from China Patent Application No. 201510683914.7, filed on Oct. 20, 2015, the contents of which are hereby incorporated by reference in their entirety for all purposes.

### TECHNICAL FIELD

The present disclosure relates to a semiconductor manufacturing technology, and particularly, relates to a silicon-on-insulator (SOI) substrate and fabrication method thereof.

### BACKGROUND

The silicon-on-insulator (SOI) substrate is one kind of substrate for fabricating integrated circuits. Comparing with the widely applied bulk silicon substrate in present, the SOI substrate has several advantages, such as the integrated circuits using the SOI substrate has small parasitic capacitance, high integration density, less short-channel effects and fast velocity, and could carry out dielectric isolation of the device in the integrated circuits to eliminate parasitic latch effect.

The three more mature fabrication methods of the SOI substrate in present include separation by implanted oxygen (SIMOX) process, silicon wafer bonding process and smart cut process. However, there is still a deficiency in present technology of fabrication method of the SOI substrate affecting the performance of the device.

### SUMMARY

Thus an object of the present invention is to provide a silicon-on-insulator (SOI) substrate and fabrication method thereof, which could delimitate the deficiency of the device formed on the SOI substrate without the hydrogen annealing process.

To solve above mentioned problems, the fabrication method of a silicon-on-insulator (SOI) substrate comprises the steps of providing a first substrate, wherein a first dielectric layer is formed on the first substrate, implanting deuterium ions into the first substrate, wherein a deuterium-impurity layer is formed in the first substrate at a predetermined depth, providing a second substrate, wherein a second dielectric layer is formed on the second substrate and bounded with the first dielectric layer, performing an annealing process, wherein microbubbles are formed in the deuterium-impurity layer, and cutting the first substrate from the deuterium-impurity layer to obtain the SOI substrate.

In an aspect of the present disclosure, the second substrate is regarded as the silicon substrate of the SOI substrate, the first dielectric layer and the second dielectric layer are regarded as the insulating layer of the SOI substrate, and a portion of the first substrate between the deuterium-impurity layer and the first dielectric layer is regarded as the upper silicon layer of the SOI substrate.

In an aspect of the present disclosure, the upper silicon layer has the deuterium ions.

In an aspect of the present disclosure, the fabrication method further comprises the step of performing chemical mechanical polishing (CMP) on the upper silicon layer

In an aspect of the present disclosure, the predetermined depth is between 50 nm and 200 nm.

In an aspect of the present disclosure, the first dielectric layer comprises silicon dioxide (SiO₂), silicon nitride (Si₃N₄) or aluminium nitride (AlN), and the thickness of the first dielectric layer is between 0.1 nm and 200 nm.

In an aspect of the present disclosure, the implanting power of the deuterium ions is between 1 KeV and 500 KeV, and the impurity concentration of the deuterium ions is between 1.0×10¹⁴/cm³ and 1.0×10¹⁸/cm³ when implanting the deuterium ions into the first substrate.

In an aspect of the present disclosure, the step of implanting the deuterium ions into the first substrate comprises implanting deuterium plasma immersion ions into the first substrate, wherein the implanting power of the deuterium plasma immersion ions is between 500 eV and 5 KeV, and the impurity concentration of the deuterium plasma immersion ions is between 1.0×10¹⁴/cm³ and 1.0×10¹⁸/cm³.

In an aspect of the present disclosure, the second dielectric layer comprises silicon dioxide (SiO₂), silicon nitride (Si₃N₄) or aluminium nitride (AlN), and the thickness of the second dielectric layer is between 0.05 nm and 10 nm.

In an aspect of the present disclosure, the first dielectric layer is bounded with the second dielectric layer between 300 and 400 degrees Celsius (° C.).

In an aspect of the present disclosure, the annealing process is performed between 600 and 800 degrees Celsius (° C.).

In an exemplary embodiment, a silicon-on-insulator (SOI) substrate is provided. The SOI substrate comprises a silicon substrate, an insulating layer formed on the silicon substrate and an upper silicon layer formed on the insulating layer, and the upper silicon layer has deuterium ions.

The method of the present invention comprises implanting deuterium ions into the first substrate. Since the mass of the deuterium ions is large, the deuterium ions are still existed in the first substrate after the annealing process, so that the upper silicon layer of the SOI substrate has the deuterium ions. When forming the device on the SOI substrate in the present invention, such as the gate oxidation layer or interface, the deuterium ions could be diffused out and bonded with dangling bonds on the interface to obtain a more stable structure. Besides, the deuterium ions could eliminate the deficiency existed in the device to avoid hot carrier tunneling field effect without hydrogen annealing. Therefore, the method of the present invention simplifies the fabrication process and enhances the device performance and reliability.

Aforesaid exemplary embodiments are not limited and could be selectively incorporated in other embodiments described herein.

### BRIEF DESCRIPTION OF THE DRAWINGS

Exemplary embodiments will be more readily understood from the following detailed description when read in conjunction with the appended drawing, in which:

FIG. 1 is a flow chart of a fabrication method of a silicon-on-insulator (SOI) substrate according to one embodiment of the present disclosure;

FIG. 2 is a cross-sectional view showing the first substrate according to one embodiment of the present disclosure;

FIG. 3 is a cross-sectional view showing implanting deuterium ions into the first substrate according to one embodiment of the present disclosure;

FIG. 4 is a cross-sectional view showing the first dielectric layer bonded with the second dielectric layer according to one embodiment of the present disclosure;

FIG. 5 is a cross-sectional view showing microbubbles formed in the deuterium-impurity layer according to one embodiment of the present disclosure; and

FIG. 6 is a cross-sectional view showing cutting the first substrate from the deuterium-impurity layer according to one embodiment of the present disclosure.

### DETAILED DESCRIPTION

The following detailed description in conjunction with the drawings of a silicon-on-insulator (SOI) substrate and fabrication method thereof of the present invention represents the preferred embodiments. It should be understood that the skilled in the art can modify the present invention described herein to achieve advantageous effect of the present invention. Therefore, the following description should be understood as well known for the skilled in the art, but should not be considered as a limitation to the present invention.

The kernel idea of the present invention is to provide the SOI substrate and fabrication method thereof. The method comprises implanting deuterium ions into the first substrate. Since the mass of the deuterium ions is large, the deuterium ions are still existed in the first substrate after the annealing process, so that the upper silicon layer of the SOI substrate has the deuterium ions. When forming the device on the SOI substrate in the present invention, such as the gate oxidation layer or interface, the deuterium ions could be diffused out and bonded with dangling bonds on the interface to obtain the more stable structure. Besides, the deuterium ions could eliminate the deficiency existed in the device to avoid hot carrier tunneling field effect without hydrogen annealing. Therefore, the method of the present invention simplifies the fabrication process and enhances the device performance and reliability.

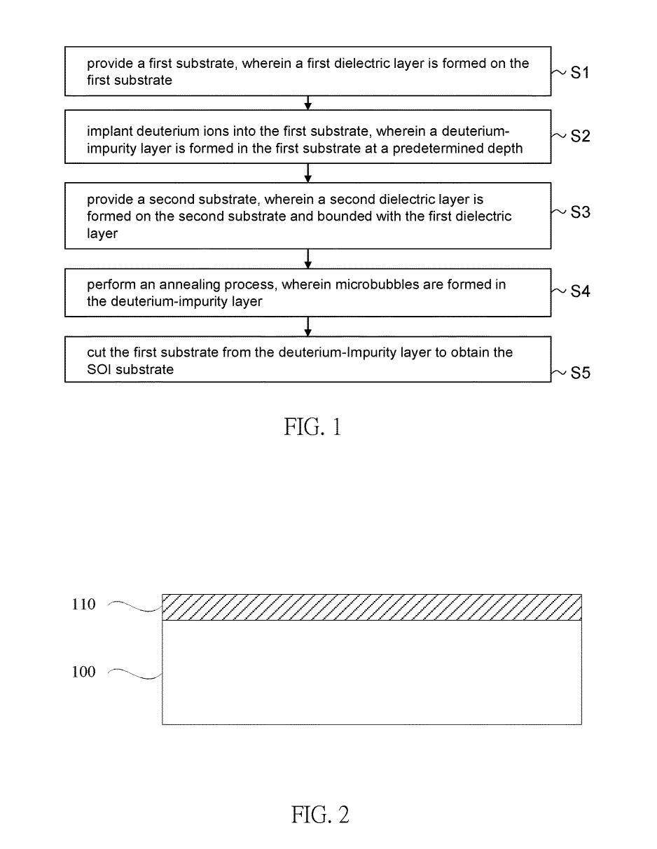

The following description would be described in conjunction with the drawings of the SOI substrate and fabrication method thereof of the present invention. FIG. 1 shows a flow chart of a fabrication method of the SOI substrate according to one embodiment of the present disclosure, and FIGS. 2 to 6 show cross-sectional views of each step of the fabrication method respectively, in which the method comprises:

Performing step S1: Referring to FIG. 2, providing a first substrate 100, in which the first substrate 100 is monocrystalline silicon substrate, and a first dielectric layer 110 is formed on the first substrate 100. In the present embodiment, the first dielectric layer 110 could be formed by chemical vapor deposition (CVD) process. The first dielectric layer 110 could comprise silicon dioxide (SiO₂), silicon nitride (Si₃N₄) or aluminium nitride (AlN), and the thickness of the first dielectric layer 110 may be between 0.1 nm and 200 nm, such as 10 nm, 50 nm, 100 nm or 150 nm.

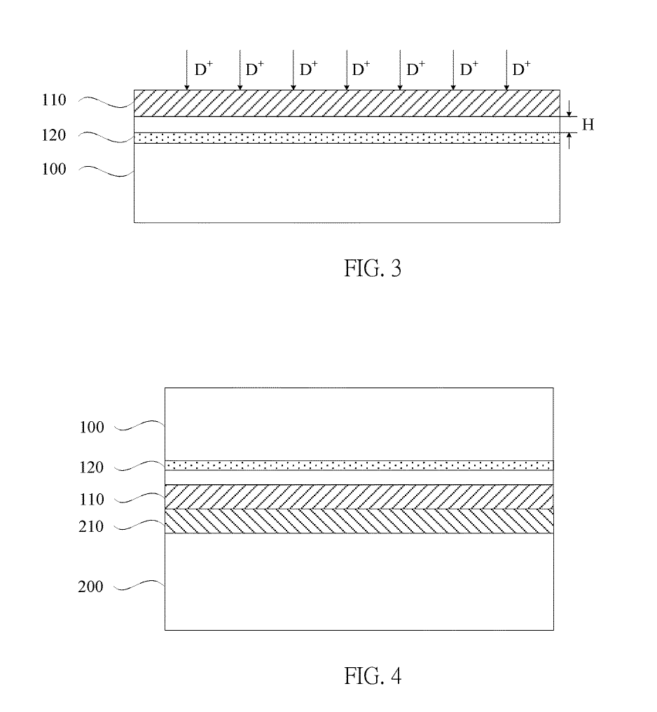

Performing step S2: Referring to FIG. 3, implanting deuterium ions D⁺ into the first substrate 100. It could be understood that deuterium ions D⁺ is the isotope of hydrogen, but has more heavy mass than hydrogen. In the present embodiment, a deuterium-impurity layer 120 is formed in the first substrate 100 at a predetermined depth H after implanting deuterium ions D⁺ into the first substrate 100, in which the predetermined depth H may be between 50 nm and 200 nm. Besides, when implanting the deuterium ions D⁺ into the first substrate 100, the implanting power of the deuterium ions D⁺ may be between 1 KeV and 500 KeV, such as 10 KeV, 50 KeV, 100 KeV, 200 KeV, 350 KeV or 450 KeV, and the impurity concentration of the deuterium ions D⁺ may be between 1.0×10¹⁴/cm³ and 1.0×10¹⁸/cm³, such as 1.2×10¹⁴/cm³, 2.02×10¹⁵/cm³, or 3.5×10¹⁷/cm³. Besides, the step of implanting the deuterium ions D⁺ into the first substrate 100 may comprise implanting deuterium plasma immersion ions into the first substrate 100, in which the implanting power of the deuterium plasma immersion ions may be between 500 eV and 5 KeV, and the impurity concentration of the deuterium plasma immersion ions may be between 1.0×10¹⁴/cm³ and 1.0×10¹⁸/cm³. It should be noted that, a trace amount of the deuterium ions D⁺ are existed in both deuterium-impurity layer 120 and the first dielectric layer 110.

Performing step S3: Referring to FIG. 4, providing a second substrate 200, in which the second substrate 200 is monocrystalline silicon substrate, and a second dielectric layer 210 is formed on the second substrate 200. In the present embodiment, the second dielectric layer 210 could be formed by CVD process. The second dielectric layer 210 could comprise SiO₂, Si₃N₄ or AlN, and the thickness of the second dielectric layer 210 may be between 0.05 nm and 10 nm. The first dielectric layer 110 could be bounded with the second dielectric layer 210 between 300 and 400 degrees Celsius (° C.), so that the first dielectric layer 110 could be bonded with the second dielectric layer 210 more tightly. In the present embodiment, the first dielectric layer 110 and the second dielectric layer 210 are regarded as an insulating layer of the SOI substrate, and they could be made from the same material or different materials.

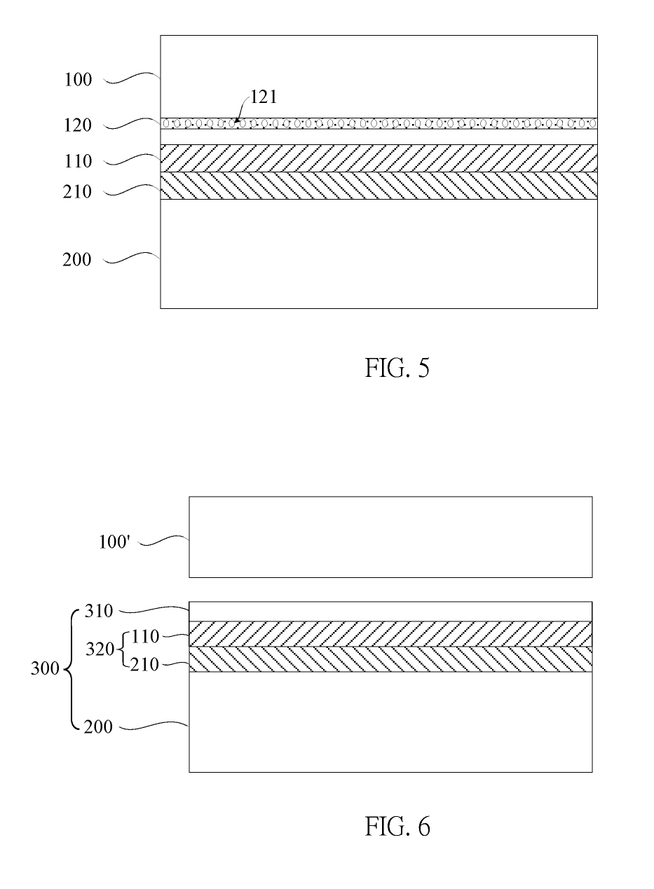

Performing step S4: Referring to FIG. 5, performing an annealing process to structure of the first dielectric layer 110 and the second dielectric layer 210 after bonding process. Micro-bubbles are formed in the deuterium-impurity layer 120 after the deuterium ions D⁺ in the deuterium-impurity layer 120 are experienced annealing, so that a porous and loose structure is formed in the deuterium-impurity layer 120, that is convenient for cutting the first substrate 100 subsequently. In the present embodiment, the deuterium-impurity layer 120 are experienced annealing between 600 and 800° C. Moreover, since the deuterium ion is larger than hydrogen ion, the deuterium ions D⁺ are still existed in the first substrate 100 after annealing process.

Performing step S5: Referring to FIG. 6, cutting the first substrate 100 from the deuterium-impurity layer 120 by a cutting knife to remove the first substrate 100 from the second substrate 200 and obtain the SOI substrate 300. It could be understood that the second substrate 200 is regarded as a silicon substrate of the SOI substrate 300, and the first dielectric layer 110 and the second dielectric layer 210 are regarded as an insulating layer 320 of the SOI substrate 300. The portion of the first substrate 100 between the deuterium-impurity layer 120 and the first dielectric layer 110 is regarded as an upper silicon layer 310 of the SOI substrate 300. In the present embodiment, after cutting the first substrate 100, the fabrication method of the SOI substrate 300 further comprises performing chemical mechanical polishing (CMP) process on the upper silicon layer 310 to eliminate an uneven surface of the upper silicon layer 310 resulting from cutting process. Besides, the first substrate 100′ after cutting could be reused for the fabrication of subsequent SOI substrate.

Correspondingly, referring to FIG. 6, the SOI substrate 300 comprises the silicon substrate 200, the insulating layer 320 formed on the silicon substrate 200 and the upper silicon layer 310 formed on the insulating layer 320, in which the SOI substrate 300 is fabricated by the above mentioned fabrication method. In the present embodiment, the silicon substrate 200 is the second silicon substrate, and the insulating layer 320 comprises the first dielectric layer 110 and the second dielectric layer 210. The first dielectric layer 110 and the second dielectric layer 210 comprise silicon dioxide (SiO₂), silicon nitride (Si₃N₄) or aluminium nitride (AlN). The upper silicon layer 310 is a portion of the first substrate 100, and the upper silicon layer 310 has deuterium ions. Therefore, when forming the device on the SOI substrate in the present invention, such as the gate oxidation layer or interface, the deuterium ions could be diffused out and bonded with dangling bonds on the interface to obtain the more stable structure. Besides, the deuterium ions could eliminate the deficiency existed in the device to avoid hot carrier tunneling field effect without hydrogen annealing. Therefore, the method of the present invention simplifies the fabrication process and enhances the device performance and reliability.

Above all, since the mass of the deuterium ions is large, the deuterium ions are still existed in the first substrate after the annealing process, so that the upper silicon layer of the SOI substrate has the deuterium ions. When forming the device on the SOI substrate in the present invention, such as the gate oxidation layer or interface, the deuterium ions could be diffused out and bonded with dangling bonds on the interface to obtain the more stable structure. Besides, the deuterium ions could eliminate the deficiency existed in the device to avoid hot carrier tunneling field effect without hydrogen annealing. Therefore, the method of the present invention simplifies the fabrication process and enhances the device performance and reliability.

While various embodiments in accordance with the disclosed principles been described above, it should be understood that they are presented by way of example only, and are not limiting. Thus, the breadth and scope of exemplary embodiment(s) should not be limited by any of the above-described embodiments, but should be defined only in accordance with the claims and their equivalents issuing from this disclosure. Furthermore, the above advantages and features are provided in described embodiments, but shall not limit the application of such issued claims to processes and structures accomplishing any or all of the above advantages.

Additionally, the section headings herein are provided for consistency with the suggestions under 37 C.F.R. 1.77 or otherwise to provide organizational cues. These headings shall not limit or characterize the invention(s) set out in any claims that may issue from this disclosure. Specifically, a description of a technology in the “Background” is not to be construed as an admission that technology is prior art to any invention(s) in this disclosure. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of such claims shall be considered on their own merits in light of this disclosure, but should not be constrained by the headings herein.

1. A fabrication method of a silicon-on-insulator (SOI) substrate, comprising the steps of:
providing a first substrate, wherein a first dielectric layer is formed on the first substrate;
implanting deuterium ions into the first substrate, wherein a deuterium-impurity layer is formed in the first substrate at a predetermined depth;
providing a second substrate, wherein a second dielectric layer is formed on the second substrate and bounded with the first dielectric layer;
performing an annealing process, wherein microbubbles are formed in the deuterium-impurity layer, the annealing process is performed between 600 and 800 degrees Celsius (° C.); and
cutting the first substrate from the deuterium-impurity layer to obtain the SOI substrate.

2. The method according to claim 1, wherein the second substrate is a silicon substrate of the SOI substrate, the first dielectric layer and the second dielectric layer are insulating layers of the SOI substrate, and a portion of the first substrate between the deuterium-impurity layer and the first dielectric layer is an upper silicon layer of the SOI substrate.

3. The method according to claim 2, wherein the upper silicon layer has the deuterium ions.

4. The method according to claim 2, further comprising the step of performing chemical mechanical polishing (CMP) on the upper silicon layer.

5. The method according to claim 1, wherein the predetermined depth is between 50 nm and 200 nm.

6. The method according to claim 1, wherein the first dielectric layer comprises silicon dioxide (SiO2), silicon nitride (Si3N4) or aluminium nitride (AlN), and the thickness of the first dielectric layer is between 0.1 nm and 200 nm.

7. The method according to claim 1, wherein the implanting power of the deuterium ions is between 1 KeV and 500 KeV, and the impurity concentration of the deuterium ions is between 1.0×1014/cm3 and 1.0×1018/cm3 when implanting the deuterium ions into the first substrate.

8. The method according to claim 1, wherein the step of implanting the deuterium ions into the first substrate comprises implanting deuterium plasma immersion ions into the first substrate, wherein the implanting power of the deuterium plasma immersion ions is between 500 eV and 5 KeV, and the impurity concentration of the deuterium plasma immersion ions is between 1.0×1014/cm3 and 1.0×1018/cm3.

9. The method according to claim 1, wherein the second dielectric layer comprises silicon dioxide (SiO2), silicon nitride (Si3N4) or aluminium nitride (AlN), and the thickness of the second dielectric layer is between 0.05 nm and 10 nm.

10. The method according to claim 1, wherein the first dielectric layer is bounded with the second dielectric layer between 300 and 400 degrees Celsius (° C.).

11. (canceled)

12. A silicon-on-insulator (SOI) substrate, comprising a silicon substrate, an insulating layer formed on the silicon substrate and an upper silicon layer formed on the insulating layer, wherein the SOI substrate is fabricated by the fabrication method according to claim 1, and the upper silicon layer has deuterium ions.

13. The SOI substrate according to claim 12, wherein the insulating layer comprises silicon dioxide (SiO2), silicon nitride (Si3N4) or aluminium nitride (AlN).
